(19) United States
(12) Patent Application Publication
(10) Pub. No.: US 2024/0290757 A1
(43) Pub. Date: Aug. 29, 2024

(54) SANDWICH PACKAGE FOR MICROELECTRONICS

(71) Applicant: SEMICONDUCTOR COMPONENTS INDUSTRIES, LLC, Phoenix, AZ (US)

(72) Inventors: Atapol PRAJUCKAMOL, Thanyaburi (TH); Chee Hiong CHEW, Seremban (MY); Yusheng LIN, Phoenix, AZ (US)

(73) Assignee: SEMICONDUCTOR COMPONENTS INDUSTRIES, LLC, Phoenix, AZ (US)

(21) Appl. No.: 18/174,837

(22) Filed: Feb. 27, 2023

(51) Int. Cl. H01L 25/07; H01L 21/48; H01L 23/00; H01L 23/498; H01L 23/538; H01L 25/00

(52) U.S. Cl. CPC H01L 25/071; H01L 21/4853; H01L 23/49811; H01L 23/538; H01L 24/37; H01L 24/40; H01L 24/41; H01L 24/84; H01L 24/95; H01L 25/50; H01L 2224/37012; H01L 2224/37147; H01L 2224/38; H01L 2224/40101; H01L 2224/40105; H01L 2224/40139; H01L 2224/40147; H01L 2224/4103; H01L 2224/4112; H01L 2224/84801; H01L 2224/8484; H01L 2224/8493

(57) ABSTRACT

A transistor configured for higher power can be constructed using multiple transistor dies coupled in parallel. This approach of distributing power and heat over multiple transistor dies can allow each transistor die to be made smaller, which can be helpful in improving yield. This is especially true for emerging technologies, such as silicon carbide (SiC). Power modules for power conversion may require a plurality of these multi-die transistors in a package. A package that accommodates the numerous connections required for a multi-die power module is disclosed. The package utilizes a lead frame to provide a three-dimensional sandwich structure in which multiple dies are positioned between two direct bonded copper (DBC) substrates.

### FIELD OF THE DISCLOSURE

The present disclosure relates to a package for a microelectronic circuit, and more specifically, to a sandwich package that facilitates the use of multiple, interconnected dies to implement the microelectronic circuit.

### BACKGROUND

A microelectronic circuit (or device) may be implemented on a single die or a plurality of dies. Implementing the microelectronic circuit (or device) on a plurality of dies may have advantages related to heat dissipation and cost but the implementation requires more interconnections.

### SUMMARY

In at least one aspect, the present disclosure generally describes a package for a microelectronic circuit (or device) with a three-dimensional structure (i.e., sandwich structure) in which a first portion of a plurality of dies are bonded to an upper direct bonded metal (i.e., DBM) substrate (i.e., upper DBM) and a second portion of the plurality of dies are bonded to a lower DBM substrate (i.e., lower DBM). Electrical connections are made to the plurality of dies by a lead frame which is positioned between (i.e., sandwiched between) the upper DBM and the lower DBM. Accordingly, the package may be referred to as a sandwich package based on the spatial relationship of the dies and lead frame between the upper DBM and the lower DBM.

In some aspects, the techniques described herein relate to a microelectronic package including: an upper direct bonded metal (DBM) substrate; a lower DBM substrate aligned with and spaced apart from the upper DBM substrate, the lower DBM substrate and the upper DBM substrate defining an interior of the microelectronic package between the lower DBM substrate and the upper DBM substrate, an upper set of dies coupled the upper DBM substrate in the interior of the microelectronic package; a lower set of dies coupled to the lower DBM substrate in the interior of the microelectronic package; and a lead frame extending from outside the interior of the microelectronic package to inside the interior of the microelectronic package; the lead frame including: a signal tab having a plurality of upward clips coupled to the upper set of dies and a plurality of downward clips coupled to the lower set of dies; and an output tab having a bidirectional clip coupled to the upper DBC substrate and the lower DBC substrate.

In some aspects, the techniques described herein relate to a half-bridge circuit including: a package including: an upper direct bonded copper (DBC) substrate including an upper high-side conductor and an upper low-side conductor; a lower DBC substrate spaced apart from the upper DBC substrate, the lower DBC substrate including a lower high-side conductor and a lower low-side conductor, an output tab including a first bidirectional clip that supports and positions the upper DBC substrate apart from the lower DBC substrate, the first bidirectional clip electrically connecting the upper low-side conductor and the lower low-side conductor to the output tab; a power tab including a second bidirectional clip that supports and positions the upper DBC substrate apart from the lower DBC substrate, the second bidirectional clip electrically connecting the upper high-side conductor and the lower high-side conductor to the power tab; a high-side transistor including: a first group of transistor-dies, wherein a first portion of the first group of transistor-dies are directly connected to the upper high-side conductor and a second portion of the first group of transistor-dies are directly connected to the lower high-side conductor; and a low-side transistor including: a second group of transistor-dies, wherein a first portion of the second group of transistor-dies are directly connected to the upper low-side conductor and a second portion of the second group of transistor-dies are directly connected to the lower low-side conductor.

In some aspects, the techniques described herein relate to a method for packaging a transistor, the method including: connecting an upper set of transistor dies to an upper direct bonded copper (DBC) substrate; connecting a lower set of transistor dies to a lower DBC substrate; positioning a lead frame between the lower DBC substrate and the upper DBC substrate to create a stack-up assembly, the positioning including: positioning bidirectional clips of the lead frame between pads on the lower DBC substrate and pads on the upper DBC substrate, the bidirectional clips configured to electrically couple the lower DBC and the upper DBC and to space the upper DBC substrate apart from the lower DBC substrate; positioning upward clips of the lead frame at pads on the upper set of transistor dies; and positioning downward clips of the lead frame at pads on the lower set of transistor dies; and heating the stack-up assembly to connect the bidirectional clips, the upward clips, and the downward clips to their respective pads in order to electrically couple the upper set of transistor dies and the lower set of transistor dies in parallel.

The foregoing illustrative summary, as well as other exemplary objectives and/or advantages of the disclosure, and the manner in which the same are accomplished, are further explained within the following detailed description and its accompanying drawings.

### BRIEF DESCRIPTION OF THE DRAWINGS

FIG. 1 is a side cross-sectional view of a package according to a possible implementation of the present disclosure.

FIG. 2 is a schematic of the half-bridge circuit according to a possible implementation of the present disclosure.

FIG. 3 is a perspective view of an upper DBC substrate and a lower DBC substrate according to a possible implementation of the present disclosure.

FIG. 4 is a perspective view of an upper DBC, substrate, lower DBC substrate, and a lead frame in a package assembly process according to a possible implementation of the present disclosure.

FIG. 5 is a magnified view of the lead frame of FIG. 4 according to a possible implementation of the present disclosure.

FIG. 6A illustrates a cross-sectional profile of an upward clip of the lead frame according to a possible implementation of the present disclosure.

FIG. 6B illustrates a cross-sectional profile of a downward clip of the lead frame according to a possible implementation of the present disclosure.

FIG. 6C illustrates a cross-sectional profile of a bidirectional clip of the lead frame according to a possible implementation of the present disclosure.

FIG. 7 is a top view of a lead frame according to a possible implementation of the present disclosure.

FIG. 8 is a perspective view of the package of a half-bridge circuit according to a possible implementation of the present disclosure.

FIG. 9 is a flowchart of a method for packaging a transistor according to a possible implementation of the present disclosure.

The components in the drawings are not necessarily to scale relative to each other. Like reference numerals designate corresponding parts throughout the several views.

### DETAILED DESCRIPTION

It may be advantageous to implement a microelectronic circuit (or device) using a plurality of dies. For example, a metal oxide semiconductor field effect transistor (MOSFET) may be implemented as a plurality of MOSFETs connected in parallel (i.e., gates connected, sources connected, and drains connected), where each MOSFET is implemented on a separate die. The parallel MOSFETs may increase an overall current carrying capacity of the device due to their current channels being connected in parallel. Further, distributing the conducted current between the plurality of MOSFETs can distribute the thermal heating over the plurality of dies, which may make cooling more efficient. Moreover, the use of multiple dies may lead to a reduction in cost by reducing a potential yield loss for each die. The approach of using multiple dies to implement a device (e.g., MOSFET) may be especially useful for silicon carbide (SIC) technology, which is relatively new and more expensive than standard Si processing.

A MOSFET implemented using a plurality of parallel-connected MOSFET dies may be referred to as a multi-die MOSFET. A plurality of multi-die MOSFETs can be interconnected in a microelectronic package to form a power module. For example, a power module may be implemented as a half-bridge circuit. The half-bridge circuit can include a high-side (H/S) MOSFET, implemented using a plurality (e.g., 4) MOSFET dies connected in parallel. The half-bridge circuit can further include a low-side (L/S) MOSFET, implemented using a plurality (e.g., 4) MOSFET dies connected in parallel.

The H/S MOSFET and the L/S MOSFET may be connected in series between an upper rail and a lower rail of a power supply. The H/S MOSFET of the half-bridge circuit may be configured to switch an upper rail voltage (i.e., P1) to a switching node (i.e., Output1) and a L/S MOSFET of the half-bridge circuit configured to switch a lower-rail voltage (i.e., N1) to the switching node (i.e., Output 1). These switching operations may be part of a power conversion (e.g., buck conversion) or power inversion (i.e., DC to AC) process.

A technical problem in using multiple dies to implement the transistors in the half-bridge circuit described above, is the high number of connections that must be made in a conveniently sized package footprint (e.g., <3 cm²). A microelectronic package is disclosed in which the dies are distributed between an upper direct bonded metal (e.g., direct bonded copper (DBC)) substrate (i.e., upper DBC substrate) and a lower direct bonded copper substrate (i.e., lower DBC substrate). The package further includes a lead frame that is (sandwiched) between the upper DBC substrate and the lower DBC substrate. The lead frame is configured to space the DBC substrates apart and to connect the dies to the terminals (e.g., P1, N1, Output1) of the microelectronic package.

The disclosed microelectronic package may have a few technical advantages. For example, the three-dimensional (i.e., upper/lower) structure can provide distributed cooling and versatility, such as in the number of dies (e.g., 4, 8, etc.) used for each device, which may be different. Further, the lead frame, which may be formed from a unibody material, may simultaneously provide the function of electrical connection and mechanical spacing.

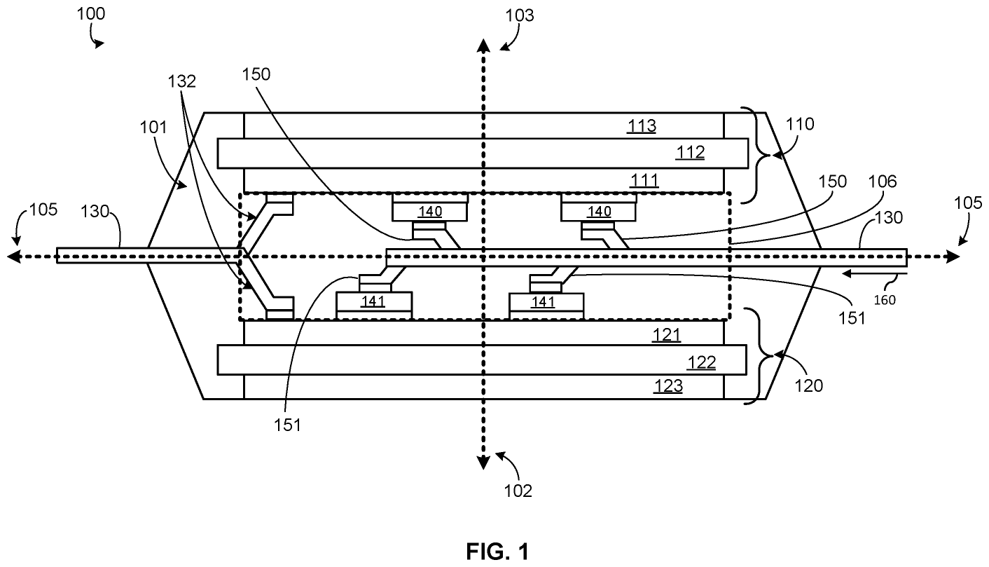

FIG. 1 is a side cross-sectional view of a microelectronic package according to a possible implementation of the present disclosure. The microelectronic package (i.e., package 100) includes an upper DBC substrate 110 and a lower DBC substrate 120, which are spaced apart to define an interior 106 of the package 100. For the discussion, a horizontal plane 105 is defined as bisecting the interior 106.

Relative positions of elements/features of the package may be described in terms of their position relative to the horizontal plane 105. For example, the upper DBC substrate 110 can be considered above the lower DBC substrate 120 because the upper DBC substrate 110 is above the horizontal plane 105, while the lower DBC substrate is below the horizontal plane 105. Accordingly, the terms upper, up, upward, above, over, and the like may refer to elements/features that are further in a positive direction 103 than other elements/features, while the terms lower, down, downward, below, under, and the like may refer to elements/features that are further in a negative direction 102 than other elements/features.

For the discussion, elements may be considered as facing the interior 106 of the package. For example, a first copper layer 111 of the upper DBC substrate 110 may be referred to as being on a front side of the upper DBC substrate 110, while a second copper layer 113 of the upper DBC substrate 110 may be referred to as being on a back side of the upper DBC substrate 110. The upper DBC substrate 110 includes an upper substrate 112 (e.g., ceramic slab) separating the first copper layer 111 and the second copper layer 113 of the upper DBC substrate 110. Likewise, a first copper layer 121 of the lower DBC substrate 120 may be referred to as being on a front side of the lower DBC substrate 120, while a second copper layer 123 of the lower DBC substrate 120 may be referred to as being on a back side of the lower DBC substrate. The lower DBC substrate 120 includes a lower substrate 122 (e.g., ceramic slab) separating the first copper layer 121 and the second copper layer 123 of the lower DBC substrate 120.

The package 100 includes a lead frame 130 that is positioned between (e.g., halfway between) the upper DBC substrate 110 and the lower DBC substrate 120. In a possible implementation, the lead frame 130 is in the horizontal plane 105. As shown, the lead frame 130 includes a plurality of upward clips 150 coupled to an upper set of dies 140 by connections on a front surface of each of the upper set of dies 140. The connections in the package can be any type that provides electrical and mechanical coupling, such as solder connections, sinter connections, or the like. The lead frame 130 further includes a plurality of downward clips 151 coupled to a lower set of dies 141 by connections (e.g., solder connections, sinter connection) on a front surface of each of the lower set of dies 141. The lead frame 130 may include a first portion within molding material 101 of the package and a second portion outside the molding material 101 of the package.

The first copper layer 111 of the upper DBC substrate 110 and the first copper layer 121 of the lower DBC substrate 120 may be coupled to the lead frame 130 by a bidirectional clip 132.

Each of the upper set of dies 140 is coupled by connections (e.g., solder connection, sinter connection) on a back surface (of each die) to the first copper layer 111 of the upper DBC substrate 110. Each of the lower set of dies 141 is coupled by connections (e.g., solder connection, sinter connection) on a back surface (of each die) to the first copper layer 121 of the lower DBC substrate 120.

Each of the dies in the upper set of dies 140 and the lower set of dies 141 may be substantially identical. For example, each die may include a transistor (e.g., SiC MOSFET transistor). The transistors of the upper set of dies 140 and the transistors of the lower set of dies 141 may be connected in parallel to form a transistor with an overall current carrying capability (i.e., power rating) that is higher than could be obtained individually using the same size die.

A transistor (e.g., SiC MOSFET) for a circuit may include a group of transistor-dies (e.g., 4 dies), with a first portion (e.g., 2 dies) of the group directly connected to the upper DBC substrate 110 and a second portion (e.g., 2 dies) of the group directly connected to the lower DBC substrate 120. Dividing the dies between the upper DBC substrate 110 and the lower DBC substrate 120 may improve cooling by distributing the heating between the upper DBC substrate 110 and the lower DBC substrate 120. For example, an upper heat sink (not shown) may be coupled to the second copper layer 113 (i.e., back side) of the upper DBC substrate 110 and a lower heat sink (not shown) may be coupled to the second copper layer 123 (i.e., back side) of the lower DBC substrate 120. The cooling may be useful for circuits used in power applications, such as the half-bridge circuit. While not required, upper dies and lower dies may alternate along the lead frame 130 in order to maximize their spacing, which can help their cooling. For example, as shown in FIG. 1, moving in a direction 160 along the lead frame 130, the lead frame includes a first upward clip connected to a first upper die, followed by a first downward clip connected to a first lower die, followed by a second upward clip connected to a second upper die, and followed by a second downward clip connected to a second lower die.

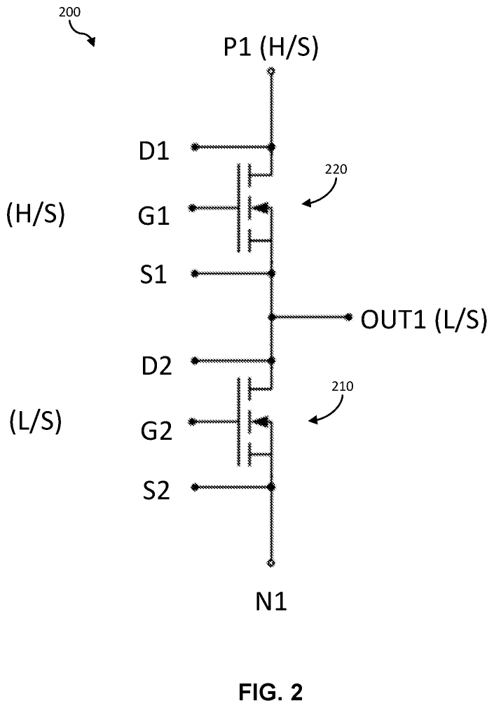

FIG. 2 is a schematic of a half-bridge circuit according to a possible implementation of the present disclosure. The half-bridge circuit 200 includes a first transistor (e.g., high-side (H/S) transistor 220). The H/S transistor 220 is coupled at a drain terminal (D1) to an upper-rail voltage (P1) (i.e., upper-rail supply) and at a source terminal (S1) to an output (OUT1) of the circuit. The H/S transistor may be configured ON (i.e., conducting) or OFF (i.e., not conducting) based on a switching signal (e.g., pulse width modulation (PWM) signal) at a gate terminal (G1) of the H/S transistor 220. The half-bridge circuit 200 further includes a second transistor (e.g., low-side (L/S) transistor 210). The L/S transistor 210 is coupled at a drain terminal (D2) to the output (OUT1) and at a source terminal (S2) to a lower-rail voltage (N1) (i.e., lower-rail supply). The L/S transistor may be configured ON (i.e., conducting) or OFF (i.e., not conducting) based on a switching signal at a gate terminal (G2) of the L/S transistor 210.

As discussed, the H/S transistor 220 may be implemented using a group of dies (e.g., four transistor dies) connected in parallel. Likewise, the L/S transistor 210 may be implemented using a plurality of dies (e.g., four transistor dies) connected in parallel. The disclosed package may be configured to include both groups of transistors.

The package for the half-bridge circuit includes tabs (i.e., leads, pins, etc.) for electrical connection with external circuitry. These tabs may be classified as power tabs or signal tabs based on the amount of current each is expected to carry, with power tabs being larger than signal tabs. The package may include a P1 power tab for connection to an upper rail voltage (e.g., positive voltage), a N1 power tab for connection to a lower-rail voltage (e.g., negative voltage), and an OUT1 power tab for connection to an output of the circuit. The package may further include a D1 signal tab for connection to the drain of the H/S transistor 220, a G1 signal tab for connection to the gate of the H/S transistor 220, and an S1 signal tab for connection to the source of the H/S transistor 220. The package may further include a D2 signal tab for connection to the drain of the L/S transistor 210, a G2 signal tab for connection to the gate of the L/S transistor 210, and an S2 signal tab for connection to the source of the L/S transistor 210. As shown in FIG. 2, the D1 signal tab may be electrically connected to the P1 power tab and the S2 signal tab may be electrically connected to the N1 power tab. Additionally, the S1 signal tab and the D2 signal tab may be electrically connected to the OUT1 power tab.

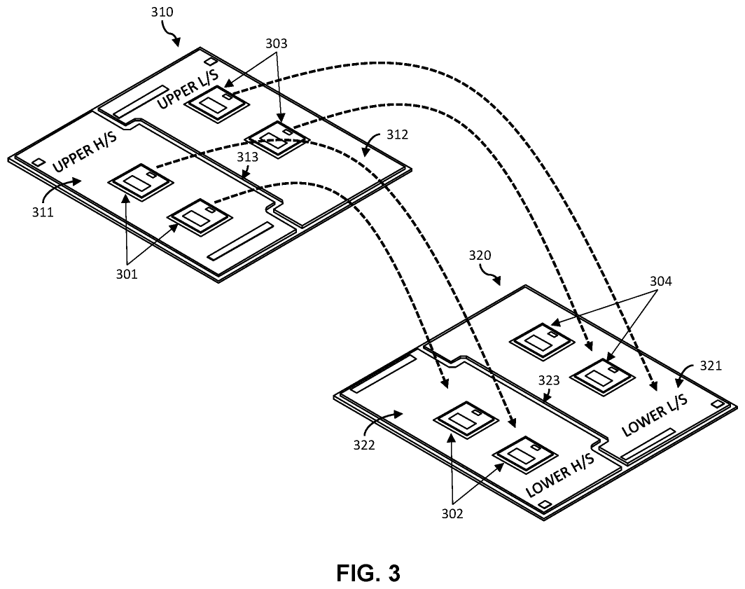

FIG. 3 is a perspective view of an upper DBC substrate 310 and a lower DBC substrate 320 prior to assembly into a package including the half-bridge circuit 200 shown in FIG. 2. An upper DBC substrate 310 includes an upper gap 313 that is made (e.g., etched, machined) into the upper conductor (e.g., see first copper layer 111 of FIG. 1). The upper gap 313 electrically isolates (i.e., insulates) an upper high-side (H/S) conductor 311 and an upper low-side (L/S) conductor 312. The lower DBC substrate 320 includes a lower gap 323 that is made (e.g., etched, machined) into the lower conductor (e.g., see first copper layer 121 of FIG. 1). The lower gap 323 insulates a lower low-side (L/S) conductor 321 and a lower high-side (H/S) conductor 322.

A H/S transistor 220 of the half-bridge circuit 200 can include two upper H/S transistor dies 301 connected (e.g., soldered, sintered) to the upper H/S conductor 311 and two lower H/S transistor dies 302 connected (e.g., soldered, sintered) to the lower H/S conductor 322. Likewise, a L/S transistor 210 of the half-bridge circuit 200 can include two upper L/S transistor dies 303 connected (e.g., soldered, sintered) to the upper L/S conductor 312 and two lower H/S transistor dies 304 connected (e.g., soldered, sintered) to the lower H/S conductor 321.

As part of an assembly process, the upper DBC substrate 310 may be flipped, as shown (dotted lines), so that the upper H/S conductor 311 is aligned with and faces the lower H/S conductor 322, and so that the upper L/S conductor 312 faces the lower L/S conductor 321. A lead frame (not shown) positioned between the upper DBC substrate 310 and the lower DBC substrate 320 may be configured (e.g., by clips) to support the DBC substrates and space them apart to define an interior 106 of the package. The lead frame may extend from outside the interior to inside the interior to make electrical connections to the dies, the (upper/lower) H/S conductors, and the (upper/lower) L/S conductors.

In the flipped condition, the two upper H/S transistor dies 301 on the upper H/S conductor 311 and the two lower H/S transistor dies 302 on the lower H/S conductor 322 alternate (e.g., upper-to-lower-to-upper-to-lower) along a direction (e.g., see FIG. 1, horizontal plane 105). Likewise, the two upper L/S transistor dies 303 on the upper L/S conductor 312 and the two lower L/S transistor dies 304 on the lower L/S conductor 321 alternate (e.g., upper-to-lower-to-upper-to-lower) along a direction (e.g., FIG. 1, horizontal plane 105).

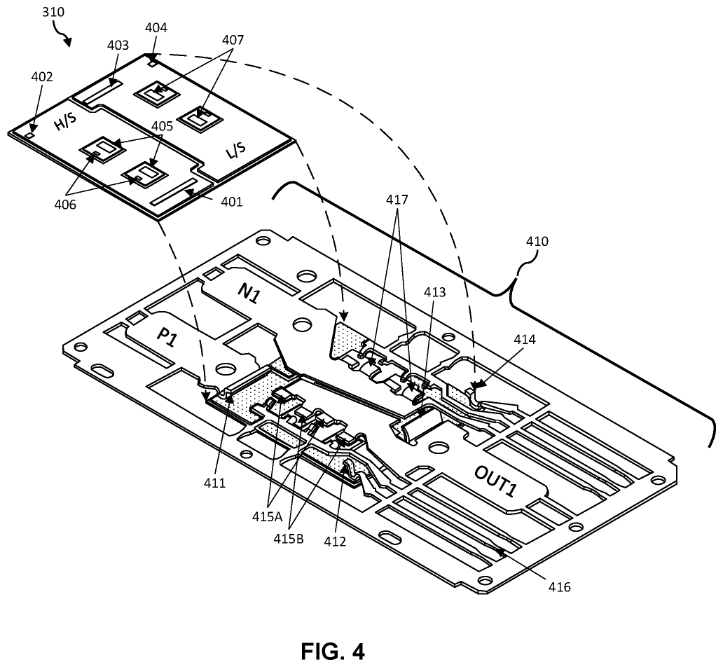

FIG. 4 is a perspective view of an upper DBC, substrate, lower DBC substrate, and a lead frame in a package assembly process according to a possible implementation of the present disclosure. The lead frame 410 may include power tabs (e.g., N1, P1) for coupling higher-power electrical signals to power the circuit of the package. The lead frame may also include an output tab (OUT1) for coupling a higher-power electrical signal output by the circuit of the package. The lead frame may also include signal tabs to couple lower power electrical signals to control the circuit of the package and/or to provide testing/monitoring of signals at points in the circuit. The signal tabs may be smaller than the power tabs because they may carry less current.

As shown in FIG. 4, the lead frame 410 can (initially) be unibody, such as being formed (e.g., cut, stamped, machined, etc.) from a plate of metal (e.g., copper). The tabs of the unibody can be separated by a trimming process prior to use.

The upper DBC substrate 310 and the lower DBC substrate 320 may be identical except for the placement of solder pads for connections with the lead frame 410. The upper H/S conductor of the upper DBC substrate 310 may include a first solder pad 401 for solder (or sinter) connection to a first bidirectional clip 411 of the power tab (P1) and a second solder pad 402 for a solder (or sinter) connection to a second bidirectional clip 412 of a first drain tab (D1). The bidirectional clips electrically connect the upper H/S conductor, lower H/S conductor, the P1 tab and the D1 tab. Drain pads of the plurality of dies comprising the H/S transistor are coupled to either the H/S conductor or the lower H/S conductor.

The upper L/S conductor of the upper DBC substrate 310 may include a third solder pad 403 for solder (or sinter) connection to a third bidirectional clip 413 of the output tab (OUT1) and a fourth solder pad 404 for a solder (or sinter) connection to a fourth bidirectional clip 414 of a second drain tab (D2). The bidirectional clips electrically connect the upper L/S conductor, lower L/S conductor, the OUT1 tab and the D2 tab. Drain pads of the plurality of dies comprising the L/S transistor are coupled to either the L/S conductor or the lower L/S conductor.

An upper set of dies are coupled at drain pads to the upper H/S conductor. The upper set of dies may include source pads 405 for solder (or sinter) connection to upward clips 415A of a portion of the lead frame coupled to the output tab (OUT1). Likewise, a lower set of dies are coupled at drain pads to the lower H/S conductor. The lower set of dies may include source pads for solder (or sinter) connection to downward clips 415B of a portion of the lead frame coupled to the output tab (OUT1) so that the source (S1) of the H/S transistor is coupled to the output of the half-bridge circuit 200.

The upper set of dies, coupled at drain pads to the upper H/S conductor, may further include gate pads 406 for solder (or sinter) connection to upward clips of a gate tab 416. Likewise, the lower set of dies, coupled at drain pads to the lower H/S conductor, include gate pads for solder (or sinter) connection to downward clips of the gate tab 416 so that the gate (G1) of the H/S transistor is coupled to gate tab 416.

Similar connections may be made for the upper set of dies coupled to the upper L/S conductor and the lower set of dies coupled to the lower L/S conductor. For example, the upper set of dies, which are coupled at drain pads to the upper L/S conductor may include source pads 407 for solder (or sinter) connection to upward clips 417 of a portion of the lead frame coupled to the (negative) power tab N1. Likewise, a lower set of dies are coupled at drain pads to the lower L/S conductor may include source pads for solder (or sinter) connection to downward clips of the portion of the lead frame coupled to the (negative power) tab (N1) so that the source (S2) of the L/S transistor is coupled to the lower rail voltage of the half-bridge circuit 200.

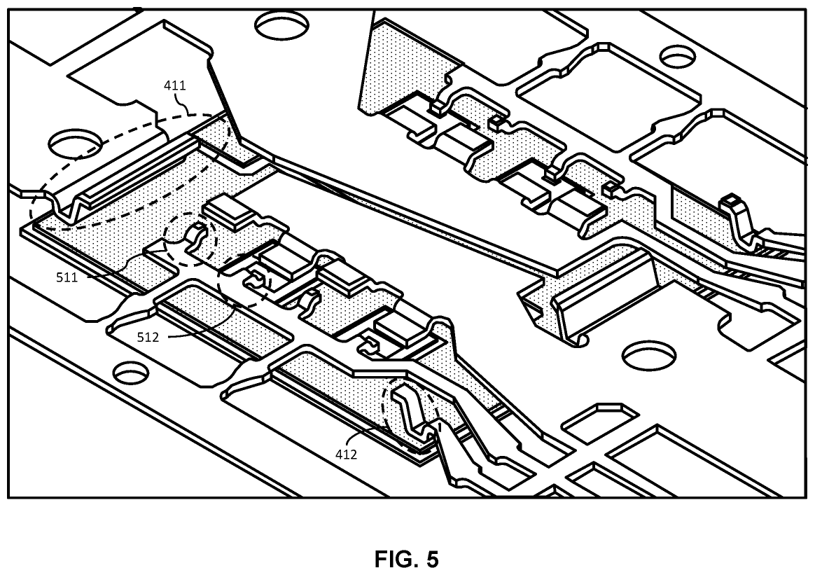

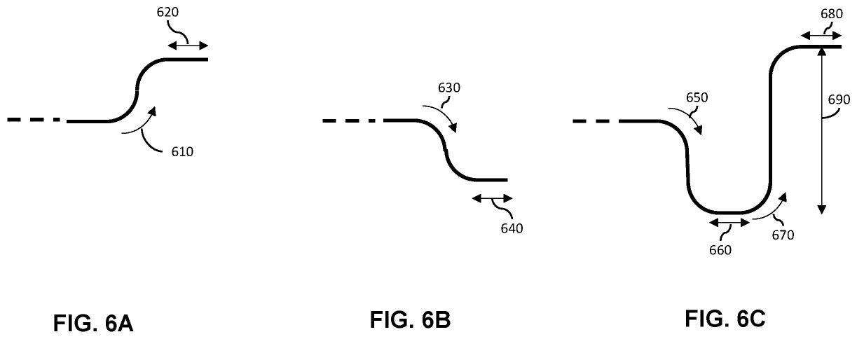

FIG. 5 is a magnified view of the lead frame of FIG. 4. As shown in FIG. 5, an upward clip 511 of the gate tab 416 includes an upward (e.g., from the horizontal plane 105) bend to an upper step that is configured to fit flush with a gate pad of a transistor die of an upper set of dies. FIG. 6A illustrates a cross-sectional profile of an upward clip of the lead frame according to a possible implementation of the present disclosure. The upward clip includes an upward bend 610 and an upper step 620. The upper step may be configured to substantially match a size of a solder pad on a transistor die. Accordingly, an upper step for a gate pad may be smaller than an upper step for a source pad.

As shown in FIG. 5, a downward clip 512 of the gate tab 416 includes a downward (e.g., from the horizontal plane 105) bend to a lower step that is configured to fit flush with a gate pad of a transistor die of a lower set of dies. FIG. 6B illustrates a cross-sectional profile of a downward clip of the lead frame according to a possible implementation of the present disclosure. The downward clip includes a downward bend 630 and a lower step 640. The lower step may be configured to substantially match a size of a solder pad on a transistor die. Accordingly, a lower step for a gate pad may be smaller than a lower step for a source pad.

As shown in FIG. 5, the first bidirectional clip 411 includes a downward (e.g., from the horizontal plane 105) bend to a lower step that is configured to fit flush with the lower H/S conductor of the lower DBC substrate. The first bidirectional clip 411 further includes an upward bend to an upper step that is configured to fit flush with the upper H/S conductor of the upper DBC substrate. FIG. 6C illustrates a cross-sectional profile of a bidirectional clip of the lead frame according to a possible implementation of the present disclosure. The bidirectional clip includes a downward bend 650, a lower step 660, an upward bend 670 to an upper step 680. The lower step 660 may be configured to substantially match a size of a solder pad on a conductor of the lower DBC substrate and the upper step 680 may be configured to substantially match a size of a solder pad on a conductor of the upper DBC substrate. A height 690 between the lower step 660 and the upper step 680 can create space between the upper DBC substrate 110 and the lower DBC substrate 120 in the package. The space (i.e., separation, gap, height, etc.) can provide clearance for an upper set of dies and a lower set of dies.

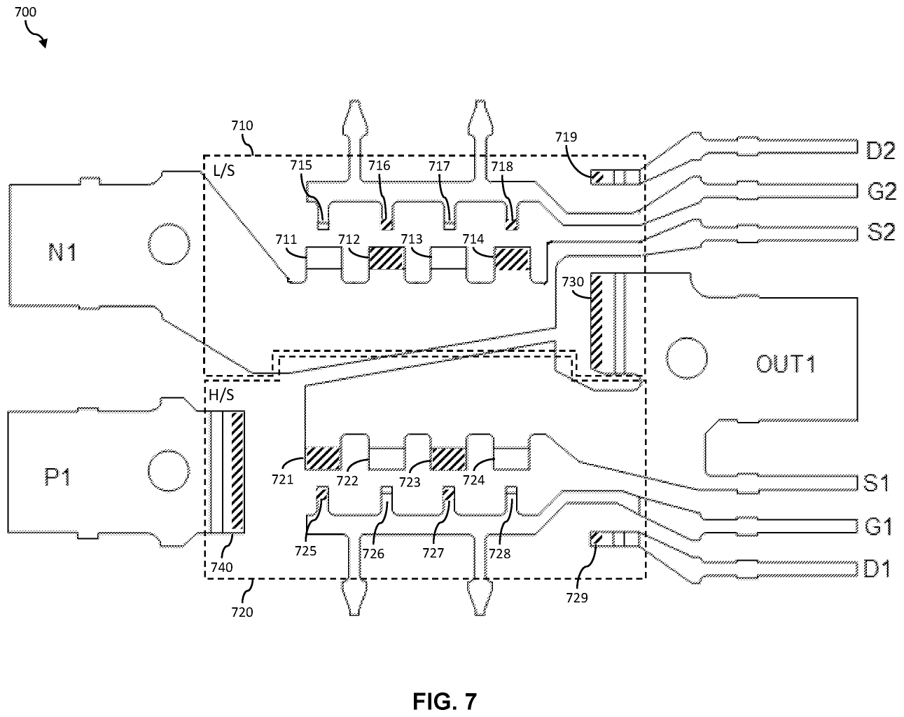

FIG. 7 is a top view of a lead frame according to a possible implementation of the present disclosure. As shown, the unibody lead frame 700 has been trimmed to separate the tabs. Also shown is an L/S area 710 corresponding to the upper and L/S conductors of the DBC substrates when viewed from above, and a H/S area 720 corresponding to the upper and lower H/S conductors of the DBC substrates when viewed from above.

The lead frame 700 includes a lower rail tab (N1). The lower rail tab (N1) includes a first downward source clip 711 for connection to a source pad of a first lower L/S die, a first upward source clip 712 for connection to a source pad of a first upper L/S die, a second downward source clip 713 for connection to a source pad of a second lower L/S die, and a second upward source clip 714 for connection to a source pad of a second upper L/S die.

The first lower L/S die is coupled at a drain terminal to the lower L/S conductor, the first upper L/S die is coupled at a drain terminal to the upper L/S conductor, the second lower L/S die is coupled at a drain terminal to the lower L/S conductor, and the second upper L/S die is coupled at a drain terminal to the upper L/S conductor. Accordingly, the lead frame 700 further includes a second drain tab (D2) for connection to a drain terminal of the L/S transistor of the half-bridge circuit (see FIG. 2). The second drain tab (D2) includes a bidirectional drain clip 719 for connection to the upper L/S conductor and the lower L/S conductor.

The lead frame 700 further includes a second gate tab (G2) for a L/S transistor. The second gate tab (G2) includes a first downward gate clip 715 for connection to a gate pad of the first lower L/S die, a first upward gate clip 716 for connection to a gate pad of the first upper L/S die, a second downward gate clip 717 for connection to a gate pad of the second lower L/S die, and a second upward gate clip 718 for connection to a gate pad of the second upper L/S die.

The lead frame 700 further includes a second source tab (S2) for a L/S transistor. The second source tab (S2) is connected to the lower rail tab (N1), which includes the upward and downward source clips for the L/S transistor.

The lead frame 700 includes an output tab (OUT1). The output tab (OUT1) includes a first upward source clip 721 for connection to a source pad of a first upper H/S die, a first downward source clip 722 for connection to a source pad of a first lower H/S die, a second upward source clip 723 for connection to a source pad of a second upper H/S die, and a second downward source clip 724 for connection to a source pad of a second lower L/S die.

The second drain terminal (D2) of the L/S transistor is further coupled to the output of the half-bridge circuit. Accordingly, the output tab (OUT1) further includes a bidirectional clip 730 for connection to the upper L/S conductor and the lower L/S conductor.

The lead frame 700 further includes a first source tab (S1) for a H/S transistor. The first source tab (S1) is connected to the output tab (OUT1), which includes the upward and downward source clips for the H/S transistor.

The lead frame 700 further includes a first gate tab (G1) for a H/S transistor. The first gate tab (G1) includes a first upward gate clip 725 for connection to a gate pad of the first upper H/S die, a first downward gate clip 726 for connection to a gate pad of the first lower H/S die, a second upward gate clip 727 for connection to a gate pad of the second upper H/S die, and a second downward gate clip 728 for connection to a gate pad of the second lower H/S die.

The first lower H/S die is coupled at a drain terminal to the lower H/S conductor, the first upper H/S die is coupled at a drain terminal to the upper H/S conductor, the second lower H/S die is coupled at a drain terminal to the lower H/S conductor, and the second upper H/S die is coupled at a drain terminal to the upper H/S conductor. Accordingly, the lead frame 700 further includes a first drain tab (D1) for connection to a drain terminal of the H/S transistor of the half-bridge circuit (see FIG. 2). The first drain tab (D1) includes a bidirectional drain clip 729 for connection to the upper H/S conductor and the lower H/S conductor.

The drain terminal of the H/S transistor in the half-bridge circuit is coupled to an upper rail voltage. Accordingly, the lead frame further includes an upper rail tab (P1). The upper rail tab (P1) includes a bidirectional clip 740 for connection to the upper H/S conductor and the lower H/S conductor.

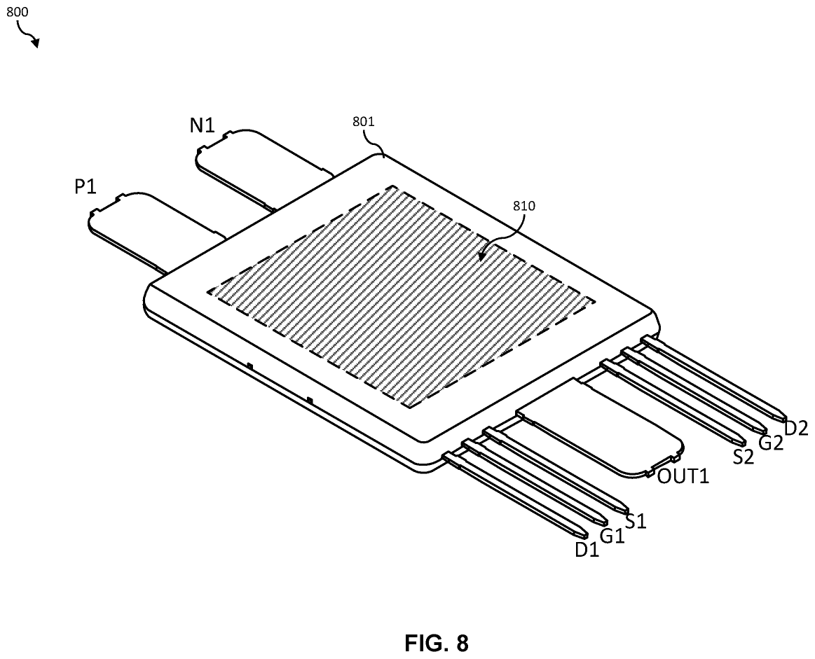

FIG. 8 is a perspective view of the package of a half-bridge circuit according to a possible implementation of the present disclosure. The package 800 includes molding material 801, which contains the dies, the upward clips, and the downward clips. A portion of the upper DBC may be not covered by the molding material 810 (i.e., exposed) to provide a surface for a heat sink (not shown) to be mounted. Similarly, a portion of the lower DBC may be exposed to provide a surface for a heat sink. A portion of the lead frame is contained in the molding material 801, while power tabs (N1, P1, OUT1) of the lead frame and signal tabs (D1, G1, S1, S2, G2, D2) of the lead frame from extend outside the molding material 801 for connection to external circuitry (not shown).

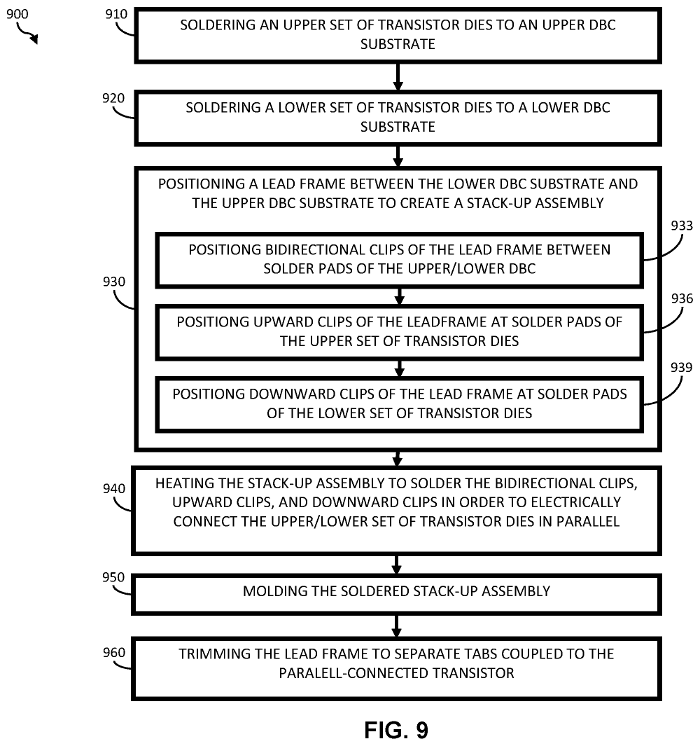

FIG. 9 is a flowchart of a method for packaging a transistor according to a possible implementation of the present disclosure. The method 900 includes soldering 910 (or sintering) an upper set of transistor dies to an upper DBC substrate and soldering 920 (or sintering) a lower set of transistor dies to a lower DBC substrate. The method 900 further includes positioning a lead frame between the lower DBC substrate (with the lower set of dies) and the upper DBC substrate (with the upper set of ides) to create 930 a stack-up assembly (e.g., see FIG. 4). At this step of the method 900, the lead frame may be a unibody lead frame, in which tabs of the package are mechanically connected. In particular, creating 930 the stack-up assembly includes positioning 933 bidirectional clips of the lead frame between solder pads of the upper DBC and the lower DBC. The creating 930 further includes positioning 936 upward clips of the lead frame at solder pads of the upper set of transistor dies, and positioning 939 downward clips of the lead frame at solder pads of the lower set of transistor dies.

After the stack-up assembly is created, the method 900 includes heating 940 the stack-up assembly to solder (or sinter) the bidirectional clips to the upper/lower DBC, to solder (or sinter) the upward clips to the upper set of dies, and to solder (or sinter) the downward clips to the lower set of dies. These connections electrically connect the transistors of the upper/lower set of transistor dies in parallel.

The method 900 includes molding 950 the stack-up assembly. The molding can be injection molding and can provide stability and protection to the electrical connections and circuitry. The injection molding may include providing an area on the upper/lower DBC for connection of a heat sink and can allow the tabs to be exposed for connection to other circuitry.

Finally, the method 900 can include trimming 960 the lead frame to separate tabs coupled to the parallel-connected transistor(s).

In the specification and/or figures, a particularly useful implementation has been disclosed, but it should be understood that the principles disclosed could be useful for other implementations that are more or less complex than the half-bridge circuit implementation described. For example, a less complex implementation for the sandwich package may include a single multi-die transistor, while a more complex implementation for the sandwich package may include a full-bridge circuit. Thus, while certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

It will be understood that, in the foregoing description, when an element is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element, there are no intervening elements present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

1. A microelectronic package comprising:
an upper direct bonded metal (DBM) substrate;
a lower DBM substrate aligned with and spaced apart from the upper DBM substrate, the lower DBM substrate and the upper DBM substrate defining an interior of the microelectronic package between the lower DBM substrate and the upper DBM substrate,
an upper set of dies coupled the upper DBM substrate in the interior of the microelectronic package;
a lower set of dies coupled to the lower DBM substrate in the interior of the microelectronic package; and
a lead frame extending from outside the interior of the microelectronic package to inside the interior of the microelectronic package; the lead frame including:
a signal tab having a plurality of upward clips coupled to the upper set of dies and a plurality of downward clips coupled to the lower set of dies; and
an output tab having a bidirectional clip coupled to the upper DBM substrate and the lower DBM substrate.

2. The microelectronic package according to claim 1, wherein the plurality of upward clips and the plurality of downward clips are configured to space the upper DBM substrate and the lower DBM substrate substantially equally on either side of the signal tab so that the signal tab approximately bisects the interior of the microelectronic package.

3. The microelectronic package according to claim 1, wherein the upper set of dies and the lower set of dies are substantially identical metal oxide semiconductor field effect transistors.

4. The microelectronic package according to claim 3, wherein the substantially identical metal oxide semiconductor field effect transistors are silicon carbide (SIC).

5. The microelectronic package according to claim 1, wherein:
the upper set of dies is an upper set of transistor-dies;
the lower set of dies is a lower set of transistor-dies;
the upper DBM substrate includes an upper high-side conductor and an upper low-side conductor, which are electrically isolated by an upper gap; and
the lower DBM substrate includes a lower high-side conductor and a lower low-side conductor that are electrically isolated by a lower gap.

6. The microelectronic package according to claim 5, wherein:
the upper set of transistor-dies are transistor dies of a low-side transistor and are coupled to the upper DBM substrate by sinter or solder connections between drain pads and the upper low-side conductor of the upper DBM substrate; and
the lower set of transistor-dies are transistor dies of the low-side transistor and are coupled to the lower DBM substrate by sinter or solder connections between drain pads and the lower low-side conductor of the lower DBM substrate.

7. The microelectronic package according to claim 5, wherein:
the upper set of transistor-dies are transistor dies of a high-side transistor and are coupled to the upper DBM substrate by sinter or solder connections between drain pads and the upper high-side conductor of the upper DBM substrate; and
the lower set of transistor-dies are transistor dies of the high-side transistor and are coupled to the lower DBM substrate by sinter or solder connections between drain pads and the lower high-side conductor of the lower DBM substrate.

8. The microelectronic package according to claim 5, wherein the bidirectional clip is soldered between the upper low-side conductor and the lower low-side conductor.

9. The microelectronic package according to claim 8, wherein the bidirectional clip is a first bidirectional clip and the lead frame further includes:
a power tab having a second bidirectional clip that is soldered between the upper high-side conductor and the lower high-side conductor, wherein the first bidirectional clip and the second bidirectional clip are configured to space the upper DBM substrate and the lower DBM substrate apart to define the interior of the microelectronic package between the lower DBM substrate and the upper DBM substrate.

10. The microelectronic package according to claim 1, wherein:
the upper set of dies and the lower set of dies are transistor-dies that each include:
a first side including a drain pad; and
a second side, opposite to the first side, that includes a gate pad and a source pad.

11. The microelectronic package according to claim 10, wherein the signal tab of the lead frame is configured to electrically connect all gate pads of the transistor-dies in parallel.

12. The microelectronic package according to claim 10, wherein:
the transistor-dies of the upper set of dies are coupled to the signal tab by sinter or solder connections between the gate pad of each transistor-die and an upward clip of the plurality of upward clips; and
the transistor-dies of the lower set of dies are coupled to the signal tab by solder connections between the gate pad of each transistor-die and a downward clip of the plurality of upward clips.

13. The microelectronic package according to claim 1, wherein:
the upper DBM substrate includes an upper low-side conductor and an upper high-side conductor that are electrically separated by an upper gap;
the lower DBM substrate includes a lower low-side conductor and a lower high-side conductor that are electrically separated by a lower gap; and
the bidirectional clip of the output tab is sintered or soldered to the upper low-side conductor on the upper DBM substrate and the lower low-side conductor on the lower DBM substrate.

14. A half-bridge circuit comprising:
a package including:
an upper direct bonded copper (DBC) substrate including an upper high-side conductor and an upper low-side conductor;
a lower DBC substrate spaced apart from the upper DBC substrate, the lower DBC substrate including a lower high-side conductor and a lower low-side conductor,
an output tab including a first bidirectional clip that supports and positions the upper DBC substrate apart from the lower DBC substrate, the first bidirectional clip electrically connecting the upper low-side conductor and the lower low-side conductor to the output tab;
a power tab including a second bidirectional clip that supports and positions the upper DBC substrate apart from the lower DBC substrate, the second bidirectional clip electrically connecting the upper high-side conductor and the lower high-side conductor to the power tab;
a high-side transistor including:
a first group of transistor-dies, wherein a first portion of the first group of transistor-dies are directly connected to the upper high-side conductor and a second portion of the first group of transistor-dies are directly connected to the lower high-side conductor; and
a low-side transistor including:
a second group of transistor-dies, wherein a first portion of the second group of transistor-dies are directly connected to the upper low-side conductor and a second portion of the second group of transistor-dies are directly connected to the lower low-side conductor.

15. The half-bridge circuit according to claim 14, wherein the first group of transistor dies and the second group of transistor dies are each a metal oxide semiconductor field effect transistor (MOSFET) that includes:
a drain pad on a first side; and
a gate pad and a source pad on a second side, the second side opposite the first side.

16. The half-bridge circuit according to claim 15, wherein:
each MOSFET of the first portion of the first group of transistor-dies is sintered or soldered at drain pads to the upper high-side conductor;
each MOSFET of the second portion of the first group of transistor dies is sintered or soldered at drain pads to the lower high-side conductor;
each MOSFET of the first portion of the second group of transistor-dies is sintered or soldered at drain pads to the upper low-side conductor; and
each MOSFET of the second portion of the second group of transistor dies is sintered or soldered at drain pads to the lower low-side conductor.

17. The half-bridge circuit according to claim 16, further including:
a first gate tab extending between the upper high-side conductor and the lower high-side conductor, the first gate tab including:
a plurality of upward clips coupled to the gate pads of each MOSFET sintered or soldered to the upper high-side conductor; and
a plurality of downward clips coupled to the gate pads of each MOSFET sintered or soldered to the lower high-side conductor; and
a second gate tab extending between the upper high-side conductor and the lower high-side conductor, the second gate tab including:
a plurality of upward clips coupled to the gate pads of each MOSFET sintered or soldered to the upper low-side conductor; and
a plurality of downward clips coupled to the gate pads of each MOSFET sintered or soldered to the lower low-side conductor.

18. The half-bridge circuit according to claim 15, wherein the MOSFET is silicon carbide (SiC).

19. A method for packaging a transistor, the method comprising:
connecting an upper set of transistor dies to an upper direct bonded copper (DBC) substrate;
connecting a lower set of transistor dies to a lower DBC substrate;
positioning a lead frame between the lower DBC substrate and the upper DBC substrate to create a stack-up assembly, the positioning including:
positioning bidirectional clips of the lead frame between pads on the lower DBC substrate and pads on the upper DBC substrate, the bidirectional clips configured to electrically couple the lower DBC and the upper DBC and to space the upper DBC substrate apart from the lower DBC substrate;
positioning upward clips of the lead frame at pads on the upper set of transistor dies; and
positioning downward clips of the lead frame at pads on the lower set of transistor dies; and
heating the stack-up assembly to connect the bidirectional clips, the upward clips, and the downward clips to their respective pads in order to electrically couple the upper set of transistor dies and the lower set of transistor dies in parallel.

20. The method for packaging a transistor according to claim 19, further comprising:
molding the stack-up assembly after heating; and
trimming the lead frame to separate tabs of the transistor.
